(19) United States
(12) Patent Application Publication
(10) Pub. No.: US 2019/0196338 A1
(43) Pub. Date: Jun. 27, 2019

(54) METHOD OF PRODUCING METAL MESH TYPE TRANSPARENT CONDUCTING FILM USING PHOTORESIST ENGRAVED PATTERN AND SURFACE MODIFICATION AND TRANSPARENT CONDUCTING FILM PRODUCED BY THE SAME

(71) Applicant: HIGH-END TECHNOLOGY CO., LTD, Gyeonggi-do (KR)

(72) Inventor: Suk Jae LEE, Gyeonggi-do (KR)

(73) Assignee: HIGH-END TECHNOLOGY CO., LTD, Gyeonggi-do (KR)

(21) Appl. No.: 16/322,173

(22) PCT Filed: Aug. 3, 2017
(86) PCT No.: PCT/KR2017/008419

§ 371 Date: Jan. 31, 2019

(30) Foreign Application Priority Data
Aug. 9, 2016 (KR) 10-2016-0101119

(51) Int. Cl. G03F 7/42; C23C 14/02; C23C 14/14; C23C 14/58; C23C 18/16; C23C 28/00; C25D 5/02

(52) U.S. Cl. CPC G03F 7/427; C23C 14/021; C23C 14/14; C23C 14/58; H01L 31/1884; C23C 28/345; C23C 18/1689; C25D 5/02; C23C 18/165

(57) ABSTRACT

Provided is a method of producing a metal mesh type transparent conducting film using a photoresist engraved pattern and surface modification including (S1) forming a photoresist layer 20 on an upper surface of a substrate 10 or an upper surface and lower surface of a substrate 10; (S2) forming an engraved pattern portion in which embossed portions 21 and engraved portions 22 are arranged in a mesh shape in the photoresist layer 20; (S3) depositing a first metal film conductive layer 40 on the engraved pattern portion of the photoresist layer 20, or growing a second metal film conductive layer 50 through a plating process on the first metal film conductive layer 40 in which deposition is completed; (S4) surface-modifying with dry ice powders a surface of the substrate in which deposition or plating is completed; and (S5) removing the embossed portions 21 of the photoresist layer 20, and by forming a thick metal film conductive layer and then performing a wet etching process, by enabling not to perform a wet etching process after forming the thick metal film conductive layer, and by facilitating desorption through surface modification using dry ice, process complexity can be improved and a defect rate can be reduced. Further, it is possible to provide a transparent conducting film having high reliability by greatly reducing visibility through upper and lower low-reflective layers deposited in the engraved portion and enabling to serve as an adhesive layer in the lower portion and as a protective layer in the upper layer.

### BACKGROUND OF THE INVENTION

### Field of the Invention

The present invention relates to a method of producing a metal mesh type transparent conducting film, and more particularly, to a method of producing a metal mesh type transparent conducting film using a photoresist engraved pattern and surface modification and a transparent conducting film produced by the same that form an engraved pattern on a substrate using photoresist and that form a metal mesh structure through vacuum deposition and plating in the formed engraved pattern and that facilitate desorption by forming scratches on a surface.

### Related Art

Nowadays, with the development of optical and electronic fields, there is a growing demand for a transparent conducting film having high light transmittance and electrical conductivity. Particularly, while a display device has a touch function for user convenience, the transparent conducting film is becoming a key component and material for electronic devices such as a flat panel display device, a solar cell, and a transparent touch panel.

Recently, the transparent conducting film used in the touch panel is made of an indium tin oxide (ITO) having excellent transparency and conductivity. However, as a transparent conducting film, an ITO material has a limit to be applied as a transparent conducting film requiring low sheet resistance due to a high sheet resistance characteristic thereof.

Therefore, various researches have been conducted to produce a transparent conductive substrate having low sheet resistance, and a method of forming a transparent material such as graphene, CNT, and Ag nanowire etc. as a substitute material of indium tin compound and various alternative techniques such as a metal mesh type transparent conducting film that enables an opaque metal conductive layer to have conductivity and transparency by forming and patterning the opaque metal conductive layer are being studied. In the metal mesh type transparent conducting film type, a line width of a mesh structure should be made as small as a few micrometers so as not to view a patterned metal wire while securing sufficient transparency after depositing and plating a metal having excellent conductivity on a substrate such as a film, but it is difficult to realize a fine line width only by wet etching.

In particular, a patterning method using photoresist of a conventional embossing method uses a process of depositing a metal film, coating photoresist thereon, forming a fine embossed pattern with the photoresist, and etching the metal film, and when a metal film layer is formed with two kinds, if the difference in etching of material of each film layer is not reduced during wet etching, there is a problem that a lower or upper metal layer is over-etched or be remained residues in a lower or upper metal layer after etching.

Further, in a metal mesh structure, when it is necessary that a thickness of the metal layer is 1 μm or more, because a process is difficult with a conventional deposition method, a conductive metal layer is formed by a plating method, which is a fast film forming method, and the formed metal conductive layer is patterned through a wet etching process. In this case, a metal film layer having a thickness of several micrometers or more has difficulty in realizing a fine line width during a subsequent wet etching process, and the burden and difficulty are very large in performing the wet etching process so that residues are not remained on the substrate.

In a metal mesh type transparent conducting film disclosed in Korea Patent Registration Publication No. 10-1319943, a metal material is deposited and patterned through exposure and etching processes. However, due to a visibility problem, a line width should be finely patterned, and micropatterning suffers from difficulties in micropattern burden and wet etching process control in the exposure process.

### PRIOR ART DOCUMENT

### Patent Document 1

Korea Patent Registration Publication No. 10-1319943

### SUMMARY OF THE INVENTION

The present invention has been made to solve the above problems and a first object of the present invention provides a method of producing a metal mesh type transparent conducting film using a photoresist engraved pattern that forms a conductive metal film by deposition or deposition and plating according to a target metal film deposition thickness by forming a mesh structure by engraving after coating photoresist.

Further, a second object of the present invention is to provide a method of producing a metal mesh type transparent conducting film using a photoresist engraved pattern and surface modification that enable to remain only deposition and plating layers or a vacuum deposition layer formed under the photoresist engraving pattern and that effectively simultaneously desorb photoresist or a conductive metal layer deposited in an upper portion through a photoresist stripping solution or a solvent after surface modification by spraying dry ice (CO₂) onto a surface of a metal layer formed on photoresist in order to effectively remove photoresist by a wet method after completion of deposition and plating of a metal film.

In an aspect, a method of producing a metal mesh type transparent conducting film using a photoresist engraved pattern and surface modification according to the present invention includes the steps of

(S1) forming a photoresist layer 20 on an upper surface of a substrate 10 or an upper surface and lower surface of a substrate 10;

(S2) forming an engraved pattern portion in which embossed portions 21 and engraved portions 22 are arranged in a mesh shape in the photoresist layer 20;

(S3) depositing a first metal film conductive layer 40 on the engraved pattern portion of the photoresist layer 20, or growing a second metal film conductive layer 50 through a plating process on the first metal film conductive layer 40 in which deposition is completed;

(S4) surface-modifying with dry ice powders a surface of the substrate in which deposition or plating is completed; and

(S5) removing the embossed portions 21 of the photoresist layer 20.

Further, in the method of producing a metal mesh type transparent conducting film using a photoresist engraved pattern and surface modification according to the present invention,

the photoresist layer of the substrate may be formed by coating with a wet method or by laminating a photoresist film type photosensitive film.

Further, in the method of producing a metal mesh type transparent conducting film using a photoresist engraved pattern and surface modification according to the present invention,

the engraved pattern portion formed in the photoresist layer may be divided into a screen portion and a circuit portion or a ground portion.

Further, in the method of producing a metal mesh type transparent conducting film using a photoresist engraved pattern and surface modification according to the present invention,

the engraved portions of the screen portion may have a width of 2 μm to 50 μm and a depth of 2 μm to 50 μm, and the embossed portion thereof may have a width of 50 μm to 1,000 μm, and

the engraved portions of the circuit portion may have a width of 5 μm to 1,200 μm and a depth of 2 μm to 50 μm.

Further, in the method of producing a metal mesh type transparent conducting film using a photoresist engraved pattern and surface modification according to the present invention,

the first metal film conductive layer at step S3 may be formed by forming a lower low-reflective layer 30 on the photoresist layer 20 and sequentially vacuum depositing on the lower low-reflective layer 30, or by vacuum depositing only the first metal film conductive layer 40 on the photoresist layer 20.

Further, in the method of producing a metal mesh type transparent conducting film using a photoresist engraved pattern and surface modification according to the present invention,

the lower low-reflection layer 30 and the first metal film conductive layer may be formed by uniformly depositing on an upper portion of the embossed portions 21 and the engraved portions 22 of the photoresist layer 20.

Further, in the method of producing a metal mesh type transparent conducting film using a photoresist engraved pattern and surface modification according to the present invention,

the first metal film conductive layer 40 serves as a seed layer for enabling the second metal film conductive layer 50 to grow in a plating process of step S3.

Further, in the method of producing a metal mesh type transparent conducting film using a photoresist engraved pattern and surface modification according to the present invention,

the first metal film conductive layer 40 and the second metal film conductive layer 50 may be deposited using one or more kinds of alloys selected from silver, copper, and aluminum or alloys containing silver, copper, and aluminum as a main component and containing an auxiliary component of a weight of 5 wt % or less of a total weight, and the lower low-reflective layer 30 and an upper low-reflective layer 60 may be made of materials containing as a main component a metal oxide capable of reducing reflectance by absorbing visible light.

Further, in the method of producing a metal mesh type transparent conducting film using a photoresist engraved pattern and surface modification according to the present invention,

The method may further include forming an upper low-reflective layer 60 for reducing reflectance of the surface on the first metal film conductive layer 40 or the second metal film conductive layer 50 between steps S3 and S4, and the upper low-reflective layer 60 may be a deposition film formed by a deposition process or an oxinitride film in which a surface of the second metal film conductive layer is formed by oxidizing or nitriding by a plasma reaction under an atmosphere of oxygen, nitrogen, or a mixed gas thereof.

Further, in the method of producing a metal mesh type transparent conducting film using a photoresist engraved pattern and surface modification according to the present invention,

the dry ice powders at step S4 may be applied onto only a surface of the embossed portions at a predetermined angle with a predetermined pressure to generate scratches.

Further, in the method of producing a metal mesh type transparent conducting film using a photoresist engraved pattern and surface modification according to the present invention,

an incidence angle of the dry ice powder to the surface may be 45 to 90°.

Further, in the method of producing a metal mesh type transparent conducting film using a photoresist engraved pattern and surface modification according to the present invention,

the lower low-reflective layer 30, the first metal film conductive layer 40, the second metal film conductive layer 50, and an upper low-reflective layer 60 above the photoresist layer 20 may be removed by removal of the photoresist layer 20 of the embossed portions 21 at step S5, and

only the lower low-reflective layer 30, the first metal film conductive layer 40, the second metal film conductive layer 50, and the upper low-reflective layer 60 in the engraved portions 22 may remain on the substrate 10.

Further, in the method of producing a metal mesh type transparent conducting film using a photoresist engraved pattern and surface modification according to the present invention,

the wet stripping solution for removing the photoresist layer 20 of the embossed portion 21 at step S5 may be an amine series solution.

The present invention also provides a metal mesh type transparent conducting film produced by the method of producing a metal mesh type transparent conducting film using a photoresist graved pattern and surface modification according to the present invention.

In a metal mesh type transparent conducting film substrate produced by the present invention, after coating or laminating photoresist on a substrate, by forming an engraving pattern through exposure and development and by depositing a low-reflective film and a conducting film layer by vacuum evaporation, when film formation is completed or when the conducting film is formed to be relatively thick, by forming a seed layer by vacuum deposition and forming a conducting film of several micrometers by a plating process, and by facilitating desorption by forming scratches or the like on the surface and by enabling not to perform a wet etching process having a high level of process control difficulty by a general method of conducting exposure and wet etching processes after forming a thick metal film conductive layer, process complexity can be improved and a defect rate can be reduced.

Further, it is possible to provide a transparent conducting film having high reliability by greatly reducing visibility through upper and lower low-reflective layers deposited in the engraved portion and enabling for the low-reflective layers to serve as an adhesive layer in the lower portion and as a protective layer in the upper layer.

### BRIEF DESCRIPTION OF THE DRAWINGS

FIG. 1 is a schematic cross-sectional view illustrating a state in which photoresist or a photoresist film type photosensitive film is attached to a transparent substrate such as a film by coating the photoresist by a wet method or by laminating the photoresist film type photosensitive film according to an embodiment of the present invention;

FIG. 2 is a cross-sectional view illustrating a metallic mesh portion and an external ground portion formed in a photoresist layer in an engraving pattern via exposure and development processes according to an embodiment of the present invention;

FIG. 3 is a cross-sectional view illustrating a lower low-reflective layer and a first metal film conductive layer deposited on engraving patterned photoresist after developing according to an embodiment of the present invention;

FIG. 4 is a cross-sectional view illustrating a second metal film conductive layer selectively plated onto only an upper portion of an embossed portion and an upper portion of an engraved portion through a plating process using a deposited first metal film conductive layer as a seed layer according to an embodiment of the present invention;

FIG. 5 is a diagram illustrating an upper low-reflective layer deposited or formed on a plating film according to an embodiment of the present invention;

FIG. 6 is a diagram illustrating a process of performing surface modification of a deposed or plated substrate surface using dry ice powders according to an embodiment of the present invention; and

FIG. 7 is a cross-sectional view illustrating a process in which a photoresist layer is removed from photoresist of an embossed portion through a wet removing process and in which a metal film conductive layer on the photoresist layer is together removed and in which thus only the metal film conductive layer in the engraved portion is left.

### DETAILED DESCRIPTION OF THE PREFERRED EMBODIMENT

Hereinafter, the operating principle of an preferred embodiment of the present invention will be described in detail with reference to the accompanying drawings. Further, detailed descriptions of well-known functions and structures incorporated herein may be omitted to avoid obscuring the subject matter of the present invention. Terms used herein are defined in consideration of functions of the present invention and may vary depending on a user's or an operator's intension and usage. Therefore, the terms used herein should be understood based on the descriptions made herein.

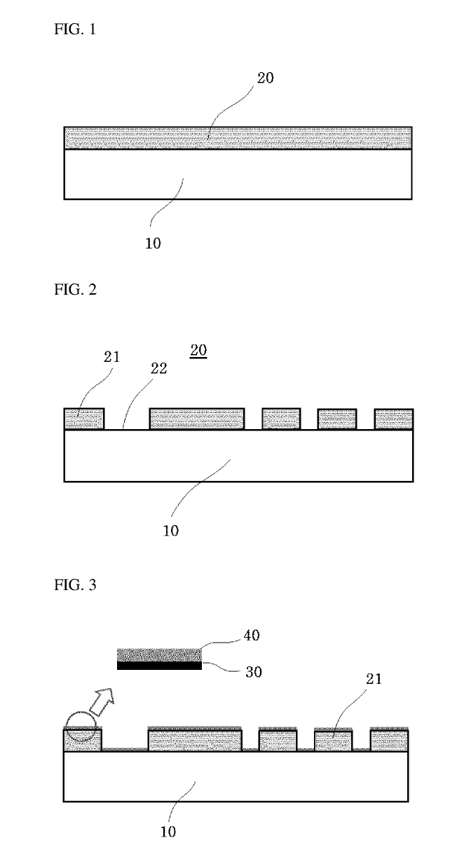

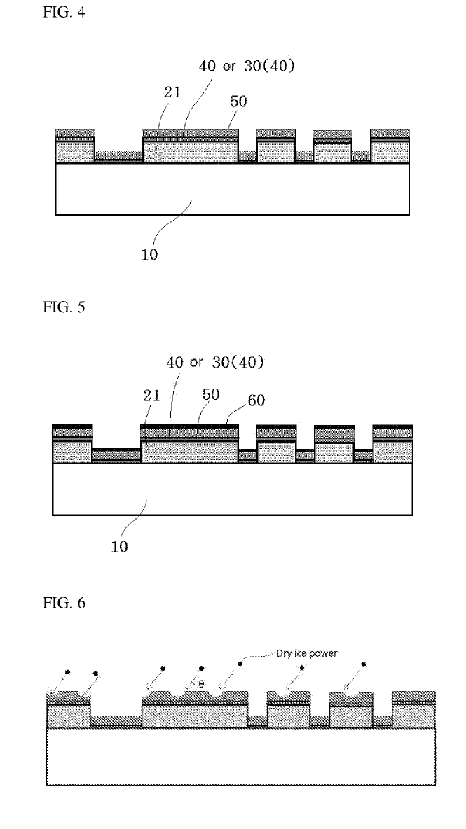

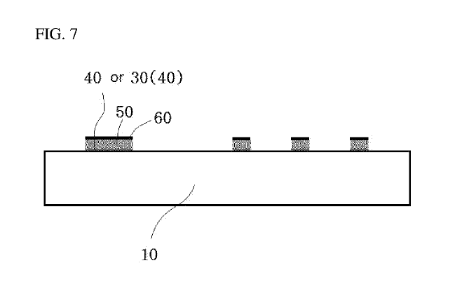

FIG. 1 is a schematic cross-sectional view illustrating a state in which photoresist or a photoresist film type photosensitive film is attached to a transparent substrate such as a film by coating the photoresist by a wet method or by laminating the photoresist film type photosensitive film according to an embodiment of the present invention, FIG. 2 a cross-sectional view illustrating a metallic mesh portion and an external ground portion formed in a photoresist layer in an engraving pattern via exposure and development processes according to an embodiment of the present invention, FIG. 3 is a cross-sectional view illustrating a lower low-reflective layer and a first metal film conductive layer deposited on engraving patterned photoresist after developing according to an embodiment of the present invention, FIG. 4 is a cross-sectional view illustrating a second metal film conductive layer selectively plated onto only an upper portion of an embossed portion and an upper portion of an engraved portion through a plating process using a deposited first metal film conductive layer as a seed layer according to an embodiment of the present invention, FIG. 5 is a diagram illustrating an upper low-reflective layer deposited or formed on a plating film according to an embodiment of the present invention, FIG. 6 is a diagram illustrating a process of performing surface modification of a deposed or plated substrate surface using dry ice powders according to an embodiment of the present invention, and FIG. 7 is a cross-sectional view illustrating a process in which a photoresist layer is removed from photoresist of an embossed portion through a wet removing process and in which a metal film conductive layer on the photoresist layer is together removed and in which thus only the metal film conductive layer in the engraved portion is left.

As shown in FIGS. 1 to 7, a process of producing a metal mesh type transparent conducting film according to an embodiment of the present invention will be described hereinafter.

(S1) Step of Forming a Photoresist Layer 20 on a Substrate 10

By coating photoresist on an upper surface or a lower surface of the substrate 10 by a wet method or by laminating a photoresist film type photosensitive film, a photoresist layer 20 is formed.

Here, the substrate 10 may be a glass substrate or a conventional substrate.

(S2) Step of Forming a Mesh-Shaped Engraved Pattern Portion in the Photoresist Layer 20

A mesh-shaped engraved pattern portion in which embossed portions 21 and engraved portions 22 are alternately arranged in the front-rear direction and a lateral direction through exposure and development of the photoresist layer 20 is formed in the substrate 10.

The engraved pattern portion of the substrate may be divided into a screen portion and a circuit portion or a ground portion, and may be provided with a mesh pattern that enters the screen portion and a wiring pattern that enters the circuit portion or the ground portion, which is a non-screen portion.

Further, a size of the screen portion and the circuit portion of the engraved pattern portion of the substrate may be made as follows to provide transparency to the display device and to provide effective electromagnetic wave shielding effect.

That is, a depth of a depressed portion of the screen portion is set to 2 μm to 50 μm, preferably 5 μm to 30 μm. Further, a width L1 of a valley of the engraved portion is 2 μm to 50 μm, preferably 5 μm to 30 μm, and a distance between the valley and the valley of the engraved portion, i.e., a width of the embossed portion is 50 μm to 1000 μm, preferably 200 μm to 800 μm to have transparency.

Further, in a wiring pattern constituting the circuit portion, a width L2 of a valley of the engraved portion is 5 μm to 1200 μm, preferably 10 μm to 1000 μm, and a depth thereof is 2 μm to 50 μm, preferably 5 μm to 30 μm.

(S3) Step of Depositing a First Metal Film Conductive Layer on the Photoresist Layer

In the engrave pattern portion of the photoresist layer, a first metal film conductive layer 40 or a lower low-reflective layer 30 and a first metal film conductive layer 40 are vacuum deposited. Here, on the photoresist layer, the lower low-reflective layer 30 and the first metal film conductive layer 40 may be sequentially vacuum deposited or only the first metal film conductive layer 40 may be deposited.

Here, the lower low-reflective layer 30 serves as an adhesive layer and simultaneously reduces high reflectance of the metal film conductive layer to reduce visibility.

Further, the first metal film conductive layer 40 serves as a seed layer in which a plating film of a plating process may grow later, and it takes a long time to deposit the conductive layer having a thickness of several micrometers only by a vacuum deposition method, thereby enhancing the problem. Further, by avoiding the need for a wet etching process having high process control difficulty by the conventional method of performing exposure and wet etching processes after forming a thick conductive layer, process complexity is improved and a product defect rate is reduced.

In this case, the lower low-reflective layer 30 and the metal film conductive layer 40 are formed in both the embossed portions 21 and the engraved portions 22 of the photoresist layer 20 by linearity of a deposition process, but are hardly formed in a wall surface of the engraving portion in a structure aspect.

(S3-1) Step of Growing a Second Metal Film Conductive Layer Having a Predetermined Thickness in the First Metal Film Conductive Layer on the Substrate.

On the first metal film conductive layer 40 deposited in an upper portion of the embossed portion 21 and the engraved portion 22 of the photoresist layer 20 on the substrate, a second metal film conductive layer 50 having a predetermined thickness is grown through a plating process.

In this case, the plating process is to grow on a deposition layer through electroplating or electroless plating, and because the first metal film conductive layer 40 has an appropriate thickness, the plating process enables the plating film to grow on the first metal film conductive layer 40 by a wet method using the first metal film conductive layer 40 as a seed layer.

The plating material is preferably copper or a copper alloy containing copper as a main component, or silver or a silver alloy containing silver as a main component. That is, a metal film constituting the first metal film conductive layer 40 and the second metal film conductive layer 50 preferable uses one or more kinds of alloys selected from main single materials such as silver, copper, or aluminum having excellent conductivity or an alloy containing one or more kinds of alloys as a main component and containing an auxiliary component in an amount of 5% or less by weight based on the total weight.

In this case, the plating film is mainly formed only in an upper portion of the embossed portion and the engraved portion but is hardly formed in an engraved portion wall surface because of a tilted structure. This is because deposition is hardly carried out in the engraved portion wall surface and thus a seed layer formed during the plating process becomes very thin or almost not, and the plating film does not grow. Further, a very thin seed layer formed in the engraved portion wall surface is lost by an electrolytic solution, which is usually acidic in the plating process.

The present invention enables selective growth of a plating film during a plating process by adjusting a seed layer thickness in each region.

In this case, a total thickness of the first metal film conductive layer 40 and the second metal film conductive layer 50 is preferably 1,000 nm to 10,000 nm, and a thickness of the lower low-reflective layer is preferably 10 nm to 50 nm.

(S3-2) Step of Forming an Upper Low-Reflective Layer in the Second Metal Film Conductive Layer on the Substrate

By forming a deposition film on the first metal film conductive layer 40 or the second metal film conductive layer 50 on the substrate 10 by a deposition process so as to reduce reflectance of the surface or by enabling the metal plating surface layer to form an oxide film, a nitride film, or a oxynitride film by a plasma reaction under an atmosphere of oxygen, nitrogen, or a mixed gas thereof, an upper low-reflective layer 60 is formed. The film thus formed absorbs visible light and has a low-reflection characteristic.

In this case, a thickness of the upper low-reflective layer is preferably 20 nm to 70 nm.

Further, the upper low-reflective layer 60 and the lower low-reflective layer 30 are mainly made of a metal oxide that may greatly reduce reflectance by absorbing visible light. In this case, by absorbing visible light by forming the upper low-reflective layer 60 and the lower low-reflective layer 30 in a partially oxygen-deficient metal oxide state instead of a complete oxide, it is preferable to make low reflection to achieve and to improve a visibility problem caused by high reflectance by a metal film of the metal film conductive layer.

Here, the low-reflective layer may be made of any material as long as it has a function of suppressing reflected light to about 20% or less of incident light, preferably about 10% or less, more preferably about 5% or less. Further, in order to impart such a function, various methods such as a known method, for example, a method of forming a layer having fine irregularities on a surface, a method of forming a layer having a predetermined refractive index, and a method of forming a laminated structure of films having two or more different refractive rates may be used.

(S4) Step of Photoresist Layer 20 and Metal Film Layer Surface Modification

In order to remove the embossed portion photoresist and the metal film layer while leaving the metal film layer in only the engraved portion, before a wet process of a lower step, a powder such as dry ice, preferably fine powders are sprayed at a predetermined angle under a predetermined pressure. In this case, an incidence angle θ of dry ice powders to the surface is preferably approximately 45° to 90° (symmetrically 90° to 135°). This is to cause damage by dry ice powders only to the embossed portion on the substrate. When the incidence angle is outside the above range, the incidence angle increases and a scratch generation force transferred to a surface of the embossing portion becomes small, thereby deteriorating the peeling effect and also affecting the engraved portion.

Because of the physically transferred kinetic energy of the sprayed dry ice, scratch-like damage occurs in the metal film layer of the surface, and a photoresist stripping solution is effectively penetrated through the scratches. Therefore, the metal film and the photoresist of the embossing portion may be simultaneously peeled and removed.

In this case, the dry ice is sprayed and applies an impact on the surface by the kinetic energy, and is vaporized immediately at a room temperature and thus no foreign matter or trace is left on the metal surface. Further, by adjusting an incidence angle sprayed on the surface of the metal film, dry ice powder particles strike only the surface of the embossed portion but are not applied to the metal film of the engraved portion.

(S5) Step of Removing the Embossed Portion 21 of the Photoresist Layer 20

After a surface of the embossed portion is modified, the photoresist layer 20 is removed in a wet method.

In this case, the photoresist layer 20, and the lower low-reflective layer 30, the first metal film conductive layer 40, the second metal film conductive layer 50, and the upper low-reflective layer 60 above the photoresist layer 20 are easily peeled off by scratches formed in the surface of the embossed portion 21, and only the first low-reflective layer 30, the first metal film conductive layer 40, the second metal film conductive layer 50, and the upper low-reflective layer 60 within the engraved portion 22 are remained on the substrate 10.

In this case, as a wet stripping solution for removing the photoresist, an amine series solution may be used.

It is preferable that such a photoresist stripper solution is used to not selectively etch the metal film conductive layer and the low-reflective layer. This is to prevent the low-reflective layer and the metal film conductive layer in the engraved portion from being etched during a wet etching process.

When selective etching is completed by the wet etching process, a transparent metal mesh type substrate embedded with a wiring layer formed with an upper low-reflective layer, a second metal film conductive layer, a first metal film conductive layer, and/or a low-reflective layer is formed only in the engraved portion.

By such a process, an exposure process and a wet etching process for patterning a thick metal film conductive layer become unnecessary.

In the present invention, the conducting film is formed at the upper surface of the substrate 10, but the present invention is not limited thereto and as described above, a metal mesh structure may be formed at both the upper surface and the lower surface of the substrate 10.

The foregoing description of the present invention is intended to be illustrative, and it will be understood by those of ordinary skill in the art that various changes in form and details may be made therein without departing from the spirit and scope of the present invention as defined by the following claims. Therefore, it should be understood that the foregoing exemplary embodiments are not limited but are illustrative.

The scope of the present invention is defined by the appended claims rather than the detailed description, and all changes or modifications derived from the meaning and scope of the claims and their equivalents are to be construed as being included within the scope of the present invention.

1.-14. (canceled)

15. A method of producing a metal mesh type transparent conducting film, the method comprising:
(S1) forming a photoresist layer on an upper surface of a substrate or an upper surface and lower surface of a substrate;
(S2) forming an engraved pattern portion in which embossed portions and engraved portions are arranged in a mesh shape in the photoresist layer;
(S3) depositing a first metal film conductive layer on the engraved pattern portion of the photoresist layer, or growing a second metal film conductive layer through a plating process on the first metal film conductive layer in which deposition is completed;
(S4) surface-modifying with dry ice powders a surface of the substrate in which deposition or plating is completed; and
(S5) removing the embossed portions of the photoresist layer.

16. The method of claim 15, wherein the photoresist layer of the substrate is formed by coating with a wet method or by laminating a photoresist film type photosensitive film.

17. The method of claim 15, wherein the engraved pattern portion formed in the photoresist layer is divided into a screen portion and a circuit portion or a ground portion.

18. The method of claim 17, wherein the engraved portions of the screen portion have a width of 2 μm to 50 μm and a depth of 2 μm to 50 μm, and the embossed portion thereof has a width of 50 μm to 1,000 μm, and
the engraved portion of the circuit portion has a width of 5 μm to 1,200 μm and a depth of 2 μm to 50 μm.

19. The method of claim 15, wherein the first metal film conductive layer at step S3 is formed by forming a lower low-reflective layer on the photoresist layer and sequentially vacuum depositing on the lower low-reflective layer, or by vacuum depositing only the first metal film conductive layer on the photoresist layer.

20. The method of claim 19, wherein the lower low-reflection layer and the first metal film conductive layer are formed by uniformly depositing on each upper portion of the embossed portions and the engraved portions of the photoresist layer.

21. The method of claim 15, wherein the first metal film conductive layer serves as a seed layer for enabling the second metal film conductive layer to grow in the plating process of step S3.

22. The method of claim 15, wherein the first metal film conductive layer and the second metal film conductive layer are deposited using one or more kinds of alloys selected from silver, copper, and aluminum or alloys containing silver, copper, and aluminum as a main component and containing an auxiliary component of a weight of 5 wt % or less of a total weight, and an lower low-reflective layer formed on the photoresist layer and an upper low-reflective layer formed on the first metal film conductive layer or the second metal film conductive layer are made of materials containing as a main component a metal oxide capable of reducing reflectance by absorbing visible light.

23. The method of claim 15, further comprising forming an upper low-reflective layer for reducing reflectance of the surface on the first metal film conductive layer or the second metal film conductive layer between steps S3 and S4,
wherein the upper low-reflective layer is a deposition film formed by a deposition process or is an oxinitride film in which a surface of the second metal film conductive layer is formed by oxidizing or nitriding by a plasma reaction under an atmosphere of oxygen, nitrogen, or a mixed gas thereof.

24. The method of claim 15, wherein the dry ice powders at step S4 are applied onto only a surface of the embossed portions at a predetermined angle with a predetermined pressure to generate scratches.

25. The method of claim 24, wherein an incidence angle of the dry ice powders to the surface is 45° to 90°.

26. The method of claim 15, wherein the lower low-reflective layer, the first metal film conductive layer, the second metal film conductive layer, and the upper low-reflective layer above the photoresist layer are removed by removal of the photoresist layer of the embossed portion at step S5, and
only the lower low-reflective layer, the first metal film conductive layer, the second metal film conductive layer, and the upper low-reflective layer in the engraved portions remain on the substrate.

27. The method of claim 26, wherein the wet stripping solution for removing the photoresist layer of the embossed portions at step S5 is an amine series solution.

28. A metal mesh type transparent conducting film produced by the method of claim 15.
